(19) United States
(12) Patent Application Publication
(10) Pub. No.: US 2025/0361648 A1
(43) Pub. Date: Nov. 27, 2025

(54) SILICON WAFER AND MANUFACTURING METHOD THEREFOR

(71) Applicant: SUMCO Corporation, Tokyo (JP)

(72) Inventors: Shunya KAWAGUCHI, Tokyo (JP); Kazuhisa TORIGOE, Tokyo (JP); Toshiaki ONO, Tokyo (JP)

(73) Assignee: SUMCO Corporation, Tokyo (JP)

(21) Appl. No.: 18/881,452

(22) PCT Filed: Jun. 1, 2023
(86) PCT No.: PCT/JP2023/020424

§ 371 Date: Jan. 6, 2025

(30) Foreign Application Priority Data
Jul. 8, 2022 (JP) 2022-110225

(51) Int. Cl. C30B 33/02; C30B 29/06; H10D 62/60

(52) U.S. Cl. CPC C30B 33/02; C30B 29/06; H10D 62/60

(57) ABSTRACT

In a silicon wafer, a density of BMD generated having a depth of up to 30 μm from a surface by a first evaluation heat treatment in which, after a heat treatment at 780° C. for 3 hours, a visualization heat treatment is performed at 950° C. to 1000° C. for 16 hours is 1×10⁷ cm⁻³ to 1×10⁸ cm⁻³, and a density of BMD generated in a bulk portion deeper than a surface layer by the first evaluation heat treatment is 1×10⁹ cm⁻³ to 7×10⁹ cm⁻³. When an average density of BMD generated is defined as a first bulk density di and an average density of BMD by a second evaluation heat treatment in which, after a heat treatment at 1150° C. for 2 minutes, the visualization heat treatment is performed is defined as a second bulk density d₂, d₂/d₁ is 0.74 to 1.02.

### FIELD OF THE INVENTION

The present invention relates to a silicon wafer and manufacturing method of the same, and particularly relates to a method of heat-treating a silicon wafer that is prepared by slicing a silicon single crystal ingot produced by the Czochralski (CZ) method. In addition, the present invention relates to a silicon wafer that is heat-treated with this heat treatment method.

### BACKGROUND OF THE INVENTION

A large number of silicon wafers that are substrate materials for semiconductor devices are manufactured using silicon single crystal ingots produced by the CZ method. The CZ method is a method where a seed crystal that is brought into contact with a silicon melt inside a quartz crucible is gradually pulled up while relatively rotating the seed crystal, thereby growing a single crystal that is larger than the seed crystal. According to the CZ method, a manufacturing yield of large-diameter silicon single crystals can be increased.

It is known that when a silicon single crystal is grown using the CZ method, oxygen that dissolves out of a surface of the quartz crucible is incorporated into the silicon melt. The oxygen in the silicon melt enters a supersaturated state in the process of the silicon single crystal being cooled, and the oxygen coheres, creating oxygen precipitate nuclei.

Oxygen precipitate density of a bulk silicon wafer immediately after the wafer is cut from the silicon single crystal ingot is extremely low, and low-density oxygen precipitate has little effect on the characteristics of a semiconductor device. However, in the process of manufacturing a semiconductor device, various heat treatments are repeatedly performed, which may increase the density of oxygen precipitate. Oxygen precipitate present in a surface layer of the silicon wafer, which is an active region of the device, can cause deterioration of device characteristics such as junction leakage. Meanwhile, oxygen precipitate present in a bulk portion other than the active region of the device functions effectively as a gettering site for capturing metallic impurities that degrade device characteristics. Therefore, preferably, oxygen precipitate in the surface layer of the silicon wafer is at low density and oxygen precipitate in a region deeper than the surface layer (wafer interior) is at high density.

In order to obtain a silicon wafer of this kind, Patent Literature 1, for example, describes a manufacturing method of a silicon wafer that includes a first heat treatment step of heating a silicon wafer at 1100° C. to 1200° C. for 1 to 30 seconds inside a furnace having a non-oxidizing atmosphere; a second heat treatment step of heating the silicon wafer, after the first heat treatment step, at 800° C. to 975° C. for 2 to 10 minutes; and a third heat treatment step of heating the silicon wafer, after the second heat treatment step, at 1000° C. to 1200° C. for 1 to 10 minutes.

### RELATED ART

### Patent Literature

Patent Literature 1: Japanese Patent Laid-open Publication No. 2021-168382

### SUMMARY OF THE INVENTION

### Problems to be Solved by the Invention

In recent years, attention has focused on a bipolar-CMOS-DMOS (BCD) process, in which bipolar, CMOS, and DMOS are formed on the same substrate, as a process for manufacturing a power management semiconductor device. A BCD process is accompanied by a high-temperature heat treatment, and therefore slip dislocation can readily occur on a wafer. In order to increase not only the gettering capability but also slip resistance of a silicon wafer, the oxygen precipitate density must be increased. Moreover, a Denuded Zone (DZ) that is approximately several tens of μm deep is necessary in the BCD process, and therefore, in some cases, an epitaxial film may be formed on the surface of the silicon wafer ahead of time. However, an epitaxial film formation process adds the issue of slipping that accompanies high-temperature heat treatment, oxygen precipitate is readily lost, and thermal stability of the oxygen precipitate also becomes questionable. Thus, increased density and stability of the oxygen precipitate are important issues in a silicon wafer used for a BCD process.

However, in the manufacturing method of the silicon wafer described in Patent Literature 1, for example, when using a bulk silicon wafer with low oxygen concentration of approximately 8×10¹⁷ atoms/cm³ (ASTM F-121, 1979, the same oxygen concentration applying hereafter), increasing oxygen precipitate density in a bulk portion is difficult because the oxygen precipitate nuclei cannot be fully grown through the first to third heat treatment steps, and the oxygen precipitate nuclei are lost in a customer's subsequent heat treatment. Meanwhile, when using a bulk silicon wafer with relatively high oxygen concentration of approximately 11×10¹⁷ atoms/cm³, the oxygen precipitate is readily generated not only in the bulk portion but also in the surface layer of the wafer, and therefore, there is a possibility of no compatibility with future BCD devices.

Accordingly, the present invention provides a silicon wafer and a manufacturing method of the silicon wafer that are capable of generating, in the bulk portion, a high density of thermally stable oxygen precipitate nuclei that are not affected by a customer's heat treatment, while reducing oxygen precipitate in the surface layer as much as possible.

### Means for Solving the Problems

In order to resolve the above concerns, a silicon wafer according to the present invention includes a surface layer having a depth of up to 30 μm from the surface, and a bulk portion that is deeper than the surface layer, and when the density of oxygen precipitate generated in the surface layer by a first evaluation heat treatment is 1.0×10⁷ cm⁻³ to 1.0×10⁸ cm⁻³, the density of oxygen precipitate generated in the bulk portion by the first evaluation heat treatment is 1.0×10⁹ cm⁻³ to 7.0×10⁹ cm⁻³, an average density of oxygen precipitate generated in the bulk portion by the first evaluation heat treatment is defined as a first bulk density d₁, and an average density of oxygen precipitate generated in the bulk portion by a second evaluation heat treatment is defined as a second bulk density d₂; a ratio of the second bulk density d₂ to the first bulk density d₁ (d₂/d₁) is in the range of 0.74 to 1.02, and the first evaluation heat treatment is a two-stage heat treatment in which, after a heat treatment at 780° C. for 3 hours, a visualization heat treatment is performed, and the second evaluation heat treatment is a two-stage heat treatment in which, after a heat treatment at 1150° C. for two minutes, the visualization heat treatment is performed, and the visualization heat treatment is a heat treatment performed at 950° C. to 1000° C. for 16 hours.

The present invention can provide a silicon wafer with an oxygen precipitate density of 1.0×10⁸ cm⁻³ or less in a surface layer after an evaluation heat treatment, and further with an oxygen precipitate density in the bulk portion that is 10 or more times higher than in the surface layer as well as being thermally stable. Therefore, yield and reliability of a semiconductor device such as a BCD manufactured using the silicon wafer can be increased.

In the present invention, a ratio (dₘₐₓ/dₘᵢₙ) of the maximum value dₘₐₓ to the minimum value dₘᵢₙ of the density of oxygen precipitate generated in the bulk portion by the first evaluation heat treatment and a ratio (dₘₐₓ/dₘᵢₙ) of the maximum value dₘₐₓ to the minimum value dₘᵢₙ of the density of oxygen precipitate generated in the bulk portion by the second evaluation heat treatment are both preferably 2 or less. In this case, the ratio (dₘₐₓ/dₘᵢₙ) of the maximum value dₘₐₓ to the minimum value dₘᵢₙ of the density of oxygen precipitate generated in the bulk portion by the first evaluation heat treatment is more preferably 1.30 or less. In addition, the ratio (dₘₐₓ/dₘᵢₙ) of the maximum value dₘₐₓ to the minimum value dₘᵢₙ of the density of oxygen precipitate generated in the bulk portion by the second evaluation heat treatment is more preferably 1.32 or less. Thereby, thermally stable oxygen precipitate that is not affected by a customer's heat treatment can be generated in the bulk portion with high density and uniformly.

In the present invention, the average density of oxygen precipitate generated in the surface layer by the first evaluation heat treatment and the average density of oxygen precipitate generated in the surface layer by the second evaluation heat treatment are both preferably 2.1×10⁷ cm⁻³ or less. Thereby, a silicon wafer can be provided in which oxygen precipitate density in the surface layer is sufficiently reduced regardless of the customer's heat treatment.

In addition, the silicon wafer according to the present invention has a silicon substrate and an epitaxial silicon film that is formed on the surface of the silicon substrate, and the silicon substrate includes a surface layer having a depth of up to 30 μm from the surface and a bulk portion that is deeper than the surface layer, and when the density of oxygen precipitate generated in the surface layer by the first evaluation heat treatment is 1.0×10⁷ to 1.0×10⁸ cm⁻³, the density of oxygen precipitate generated in the bulk portion by the first evaluation heat treatment is 1.0×10⁹ to 7.0×10⁹ cm⁻³, the average density of oxygen precipitate generated in the bulk portion by the first evaluation heat treatment is defined as a first bulk density, and the average density of oxygen precipitate generated in the bulk portion by the second evaluation heat treatment is defined as a second bulk density; a ratio of the second bulk density to the first bulk density is in a range of 0.98 to 1.02, and the first evaluation heat treatment is a two-stage heat treatment in which, after a heat treatment at 780° C. for 3 hours, a visualization heat treatment is performed, and the second evaluation heat treatment is a visualization heat treatment, and the visualization heat treatment is a heat treatment at 950° C. to 1000° C. for 16 hours.

The present invention can provide a thermally stable epitaxial silicon wafer with an oxygen precipitate density in the surface layer after the evaluation heat treatment that is low at 1.0×10⁸ cm⁻³ or less, and further an oxygen precipitate density in the bulk portion that is 10 or more times higher than in the surface layer. Therefore, yield and reliability of a semiconductor device such as a BCD manufactured using the epitaxial silicon wafer can be increased.

In the present invention, the ratio (dₘₐₓ/dₘᵢₙ) of the maximum value dₘₐₓ to the minimum value dₘᵢₙ of the density of oxygen precipitate generated in the bulk portion by the first evaluation heat treatment and the ratio (dₘₐₓ/dₘᵢₙ) of the maximum value dₘₐₓ to the minimum value dₘᵢₙ of the density of oxygen precipitate generated in the bulk portion by the second evaluation heat treatment are both preferably 2 or less. In this case, the ratio (dₘₐₓ/dₘᵢₙ) of the maximum value dₘₐₓ to the minimum value dₘᵢₙ of the density of oxygen precipitate generated in the bulk portion by the first evaluation heat treatment is more preferably 1.29 or less. In addition, the ratio (dₘₐₓ/dₘᵢₙ) of the maximum value dₘₐₓ to the minimum value dₘᵢₙ of the density of oxygen precipitate generated in the bulk portion by the second evaluation heat treatment is more preferably 1.35 or less. Thereby, thermally stable oxygen precipitate that is not affected by a customer's heat treatment can be generated in the bulk portion at a high density and uniformly.

Furthermore, a manufacturing method of a silicon wafer according to the present invention includes a first heat treatment step of heating a silicon wafer at a first temperature with an oxygen concentration of 7×10¹⁷ atoms/cm³ to 10×10¹⁷ atoms/cm³ (ASTM F-121, 1979); a second heat treatment step of heating the silicon wafer, after the first heat treatment step, at a second temperature that is lower than the first temperature; and a third heat treatment step of heating the silicon wafer, after the second heat treatment step, at a third temperature that is higher than the second temperature, and the first temperature is 1210° C. to 1250° C., and a sustained time of the first temperature is 10 to 60 seconds; the second temperature is 800° C. to 975° C., and the sustained time of the second temperature is 2 to 10 minutes; and the third temperature is 1150° C. to 1250° C., and the sustained time of the third temperature is 5 to 15 minutes.

According to the present invention, through the first heat treatment step with a high temperature in a relatively short time; the second heat treatment step with a low temperature in a relatively long time; and furthermore the third heat treatment step with a temperature higher than the second heat treatment step, while thermally stable oxygen precipitate nuclei are generated inside the silicon wafer at high density, the oxygen precipitate nuclei can be reduced in the wafer surface layer. Accordingly, it is possible to manufacture a silicon wafer having a high density of thermally stable oxygen precipitate nuclei that are not affected by a customer's heat treatment in the bulk portion, as well as a low density of oxygen precipitate nuclei in a formation region of the device.

Preferably, the first heat treatment step is performed in a non-oxidizing atmosphere that contains ammonia or nitrogen, and the second and the third heat treatment steps are performed in a non-oxidizing atmosphere that does not contain ammonia or nitrogen. By performing the first heat treatment step in the non-oxidizing atmosphere that contains ammonia or nitrogen, a nitrogen film is formed on a wafer surface and voids can be introduced inside the wafer through the nitrogen film, and thereby the density of oxygen precipitate nuclei inside the wafer can be increased.

In the present invention, a rate of temperature increase to the first temperature and a rate of temperature increase from the second temperature to the third temperature are preferably 10° C./sec to 50° C./sec. Further, a rate of temperature decrease from the first temperature to the second temperature is preferably 20° C./sec to 120° C./second. Thereby, thermally stable oxygen precipitate nuclei can be generated at high density.

In the present invention, the silicon wafer prior to heat treatment in the first heat treatment step is preferably cut from a denuded zone of the silicon single crystal ingot without aggregates of interstitial silicon point defects and aggregates of vacancy point defects. Accordingly, a thermally stable silicon wafer can be manufactured where the density of the oxygen precipitate nuclei in the surface layer is low and the density of the oxygen precipitate nuclei in the bulk portion is high. Therefore, yield and reliability of a semiconductor device such as a BCD manufactured using the silicon wafer can be increased.

### Effect of the Invention

The present invention can provide a silicon wafer and a manufacturing method of the silicon wafer that are capable of generating, in the bulk portion, a high density of thermally stable oxygen precipitate that is not affected by a customer's heat treatment, while reducing oxygen precipitate in the surface layer as much as possible.

### BRIEF DESCRIPTION OF THE DRAWINGS

FIG. 1 is a flow chart schematically illustrating a method of manufacturing a silicon single crystal according to an embodiment of the present invention.

FIG. 2 is a flow chart describing a process of heat treating a silicon wafer.

FIG. 3 is a graph illustrating temperature changes during heat treatment, with the horizontal axis representing time and the vertical axis representing heating temperature, respectively.

FIGS. 4A to 4I are schematic views illustrating changes that occur in the silicon wafer during the first to third heat treatments.

FIG. 5 is a schematic view illustrating a method of measuring an oxygen precipitate density of the silicon wafer using light-scattering tomography.

FIG. 6 is a schematic view illustrating an evaluation protocol for determining stability and uniformity of the manufactured silicon wafer.

### MODE FOR CARRYING OUT THE INVENTION

Hereafter, a preferred embodiment of the present invention is described in detail with reference to the attached drawings.

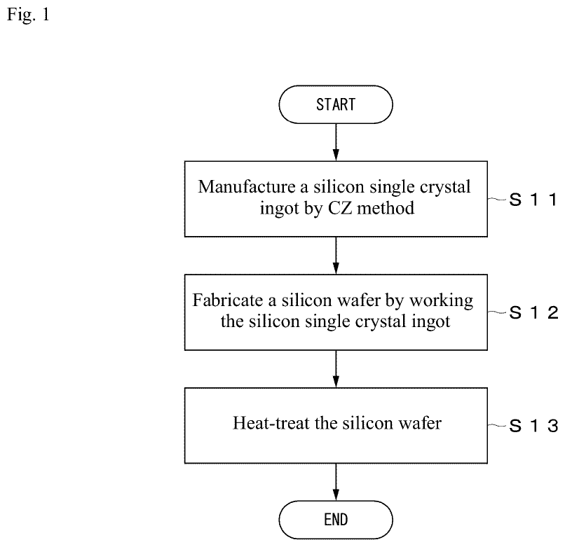

FIG. 1 is a flow chart schematically illustrating a method of manufacturing a silicon single crystal according to an embodiment of the present invention.

As illustrated in FIG. 1, a manufacturing method of the silicon wafer according to the present embodiment includes a step S11 of manufacturing a silicon single crystal ingot by the Czochralski (CZ) method, a step S12 of working the silicon single crystal ingot to fabricate a silicon wafer, and a step S13 of heat-treating the silicon wafer.

In step S11 of manufacturing the silicon single crystal ingot, polycrystalline silicon filled in a quartz crucible is heated in a CZ furnace to create a silicon melt. Next, a seed crystal is brought into contact with the silicon melt and by gradually pulling the seed crystal up while rotating the seed crystal and the quartz crucible, a large single crystal is grown on a bottom end of the seed crystal.

Next, in step S12 of fabricating the silicon wafer, the silicon single crystal ingot is sliced with a wire saw or the like, after which the slice is lapped, etched, mirror polished, washed, and so on, completing a bulk silicon wafer (polished wafer) as an intermediate product. The oxygen concentration of a CZ silicon wafer fabricated in this way is preferably 7×10¹⁷ atoms/cm³ to 10×10¹⁷ atoms/cm³ (ASTM F-121, 1979). When the concentration is lower than 7×10¹⁷ atoms/cm³, stable oxygen precipitate cannot be generated in the bulk portion at high density. When the concentration is higher than 10×10¹⁷ atoms/cm³, oxygen precipitate in a surface layer cannot be sufficiently reduced.

In this example, preferably the silicon wafer is substantially free of Crystal Originated Particle (COP) defects, a so called COP-free wafer. Specifically, the silicon wafer is preferably cut from a denuded zone of the silicon single crystal ingot with no aggregates of interstitial silicon point defects and aggregates of vacancy point defects. The crystal originated particle (COP) is a crystallographically perfectly oriented octahedral cavity and inner walls thereof are normally covered with a 1 to 4 nm-thick oxide film. Crystal defects related to vacancy such as COP defects, similar to the oxygen precipitate in the surface layer, can cause issues in a semiconductor device. Examples of the device issues include reduced gate oxide integrity (GOI) and current leak at a PN junction. In order to address these issues, in some device applications, a low defect crystal growth method can be applied to reduce the number of cavity defects in a device region near the surface. Changing crystal pull speed and crystal cooling speed may reduce a cavity defect level. This allows recombining voids and interstitial silicon atoms, cohering the voids, and controlling oxygen concentration, and surface defects are reduced. In the COP-free wafer, “substantially free of COP” means that the density of COP formed by aggregates of vacancy point defects is 1×10⁵ cm⁻³ or less.

In the step S13 of heat-treating the silicon wafer, the wafer undergoes heat treatment in three stages of temperature ranges within a rapid thermal annealing (RTA) furnace, generating a high density of thermally stable oxygen precipitate nuclei. Here, the phrase “thermally stable” means that there is sufficient density for gettering of metal impurities and maintaining wafer strength in a wafer shipment state and the density is not affected by subsequent heat treatment by a customer's device. In addition, “high density” refers to a density of at least 1×10⁹/cm³, preferably around 5×10⁹/cm³ or more.

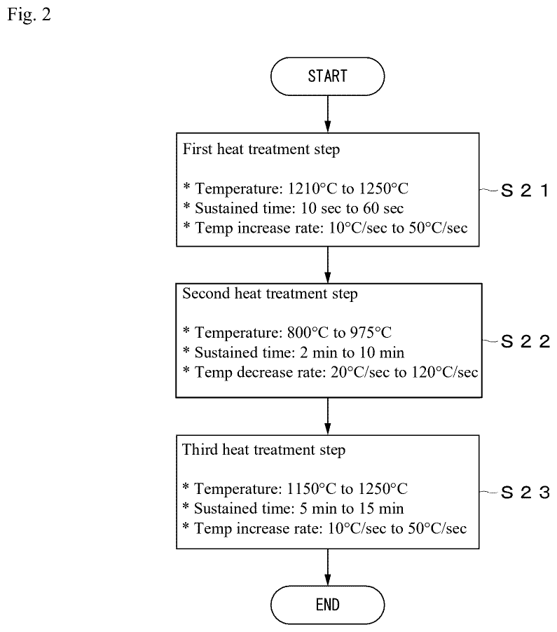

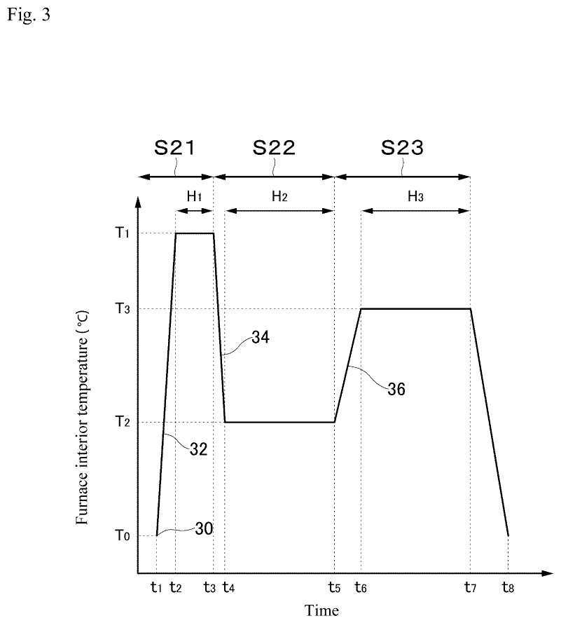

FIG. 2 is a flow chart illustrating step S13 of heat treating the silicon wafer. FIG. 3 is a graph illustrating temperature changes during the heat treatment, with the horizontal axis representing time and the vertical axis representing heating temperature, respectively.

As illustrated in FIGS. 2 and 3, a method for heat treating a silicon wafer according to an embodiment of the present invention includes a first heat treatment step S21 of heating the silicon wafer in the RTA furnace at a first temperature T₁; a second heat treatment step S22 of heating the silicon wafer, after the first heat treatment step S21, at a second temperature T₂ that is lower than the first temperature T₁; and a third heat treatment step S23 of heating the silicon wafer, after the second heat treatment step S22, at a third temperature T₃ that is higher than the second temperature T₂. In the present embodiment, the first to third heat treatment steps S21 to S23 are preferably performed continuously in the same RTA furnace. However, after the first heat treatment step S21 is performed in the RTA furnace, the wafer may be removed from the RTA furnace and the second heat treatment step S22 and the third heat treatment step S23 may be performed in different heat treatment devices.

The first heat treatment step S21 is a rapid heat treatment that is performed in an RTA furnace with a non-oxidizing atmosphere. The non-oxidizing atmosphere is preferably an inert gas containing ammonia or nitrogen, and the inert gas is preferably Ar gas. In a high-temperature heat treatment with a non-oxidizing atmosphere, a large number of voids can be introduced inside the wafer, and thereby the density of oxygen precipitate nuclei inside the wafer can be increased. Furthermore, by using Ar gas containing ammonia or nitrogen, a nitrogen film is formed on a wafer surface and voids can be introduced inside the wafer through the nitrogen film, and thereby the density of oxygen precipitate nuclei inside the wafer can be increased. In addition, minute oxygen precipitate nuclei generated during crystal growth are present in the silicon wafer, but the oxygen precipitate nuclei in the surface layer of the wafer can be reduced through the rapid heat treatment as described above.

The first temperature T₁ in the first heat treatment step S21 is preferably approximately 1210° C. to 1250° C. This is because when the first temperature T₁ is lower than approximately 1180° C., the oxygen precipitate nuclei in the surface layer cannot be sufficiently reduced, and because when the first temperature T₁ is higher than approximately 1250° C., the probability of slip dislocation occurring in the silicon wafer increases. A rate of temperature increase (32) when switching from a standby temperature T₀ (30) such as room temperature or the like to the first temperature T₁ is preferably about 10° C./sec to 50° C./sec.

A sustained time H₁ for the first temperature T₁ in the first heat treatment step S21 is preferably about 10 to 60 seconds. This is because when the sustained time H₁ for the first temperature T₁ is less than about 10 seconds, the density of the oxygen precipitate nuclei in the surface layer cannot be sufficiently reduced, and because even when the sustained time H₁ is greater than about 60 seconds, not only is there no observable increase in the number of voids, but the probability of slip dislocation occurring increases. A large number of voids can be introduced inside the silicon wafer while losing the oxygen precipitate nuclei in the surface layer by the first heat treatment step S21.

In the second heat treatment step S22, the silicon wafer that was heat-treated in the first heat treatment step S21 is heat-treated at the second temperature T₂, which is lower than the first temperature T₁. Unlike the first heat treatment step S21, the second heat treatment step S22 is preferably performed in a non-oxidizing atmosphere that does not contain ammonia or nitrogen. Therefore, after the first heat treatment step S21 ends, the atmospheric gas inside the RTA furnace is replaced.

The second temperature T₂ in the second heat treatment step S22 is preferably approximately 800° C. to 975° C. This is because when the second temperature T₂ is less than approximately 800° C., thermally stable oxygen precipitate nuclei cannot be generated, and when the second temperature T₂ is greater than approximately 975° C., oxygen precipitate nuclei cannot be generated at high density. A rate of temperature decrease (34) when switching from the first temperature T₁ to the second temperature T₂ is preferably about 20° C./sec to 120° C./sec.

A sustained time H₂ for the second temperature T₂ in the second heat treatment step S22 is preferably about 2 to 10 minutes. This is only because when the sustained time H₂ for the second temperature T₂ is less than about 2 minutes, the oxygen precipitate nuclei cannot be generated at high density, and when the sustained time H₂ is longer than about 10 minutes, cost only increases without any increase in oxygen precipitate nuclei density. Oxygen precipitate nuclei can be generated stably and at high density inside the silicon wafer by the second heat treatment step S22.

In the third heat treatment step S23, the silicon wafer that was heat-treated in the second heat treatment step S22 is heat-treated at the third temperature T₃, which is higher than the second temperature T₂. Similar to the second heat treatment step S22, the third heat treatment step S23 is preferably performed in a non-oxidizing atmosphere that does not contain ammonia or nitrogen.

The third temperature T₃ in the third heat treatment step S23 is preferably approximately 1150° C. to 1250° C. This is because when the third temperature T₃ is lower than approximately 1150° C., the oxygen precipitate nuclei cannot achieve a thermally stable state, and when the third temperature T₃ is higher than approximately 1250° C., the probability of slip dislocation occurring increases. A rate of temperature increase (36) when switching from the second temperature T₂ to the third temperature T₃ is preferably about 10° C./sec to 50° C./sec. Thereby, the density of oxygen precipitate nuclei can be increased and the nuclei can be made more thermally stable.

A sustained time H₃ for the third temperature T₃ in the third heat treatment step S23 is preferably about 5 to 15 minutes. This is only because when the sustained time H₃ for the third temperature T₃ is less than about 5 minutes, the high-density oxygen precipitate nuclei cannot become fixed, and when the sustained time H₃ is longer than about 15 minutes, cost increases without any particular increase in an oxygen precipitate nuclei stabilization effect.

The third heat treatment step S23 can stabilize the oxygen precipitate nuclei formed in the silicon wafer and can inhibit a surplus of voids inside the wafer from diffusing out and generating surplus oxygen precipitate in a customer's subsequent heat treatment. Moreover, the density of oxygen precipitate generated in the surface layer with up to 30 μm from the surface of the wafer can be reduced to 1/100 or less in the bulk portion by losing the oxygen precipitate nuclei in the wafer surface that is newly formed in the second heat treatment step S22.

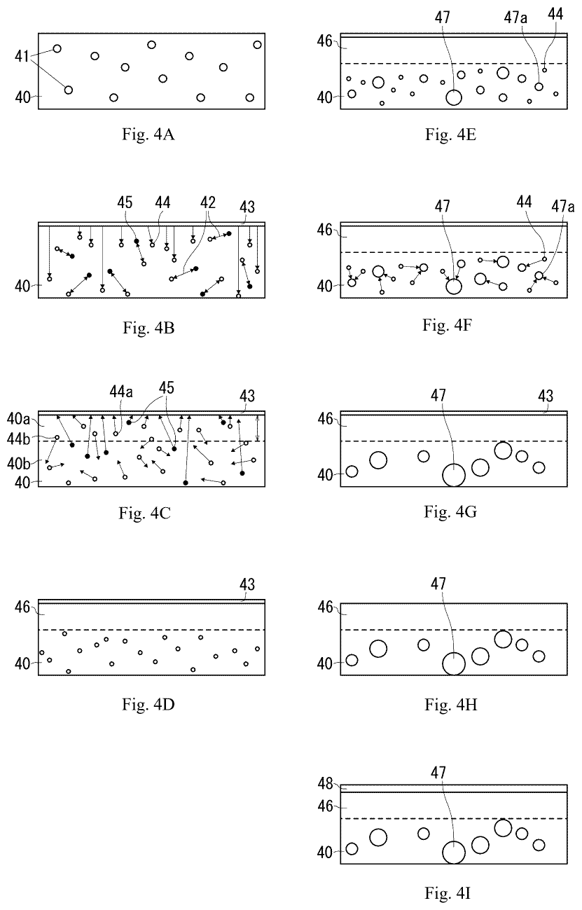

FIGS. 4A to 4I are schematic views illustrating changes that occur in a silicon wafer 40 during the first to third heat treatment steps S21 to S23. As illustrated in FIG. 4A, a large number of minute oxygen precipitate nuclei 41 generated during crystal growth are present in the silicon wafer 40. As illustrated in FIG. 4B, during the sustained time H₁ in the first heat treatment step S21, it is understood that minute oxygen precipitate nuclei 41 are lost at the same time as formation of a Frenkel pair 42 of a void 44 and an interstitial silicon atom 45 occurs. Additional voids 44 are displaced to inside the silicon wafer 40 from an interface between an Si₃N₄ layer 43 and the silicon wafer 40. With this heat treatment, oxygen precipitate nuclei 41 generated during crystal growth are lost, thereby sufficiently reducing oxygen precipitate nuclei in a DZ 46 formed in the subsequent process.

Next, as shown in FIG. 4C, outward diffusion of the interstitial silicon atoms 45 and a portion 44a of voids, and displacement of a portion 44b of voids from an upper zone 40a to a lower zone 40b of the wafer occur during the decrease in temperature between times t₃ and t₄, and the DZ 46 with a low density of oxygen precipitate nuclei can be formed as shown in FIG. 4D.

Next, as shown in FIG. 4E, during the sustained time H₂ in the second heat treatment step S22, oxygen precipitate nuclei 47 and 47a are created from combining of the voids 44 and the nuclei reach a size large enough to stabilize. However, some voids 44 remain. As shown in FIG. 4F, during the sustained time H₃ in the third heat treatment step S23, the remaining voids 44 and small oxygen precipitate nuclei 47a further recombine into larger and more stable oxygen precipitate nuclei 47. As shown in FIG. 4G, large stable oxygen precipitate nuclei 47 are created and the DZ 46 with preferable width is formed, and thereby ultimately oxygen precipitate density in the surface layer within 30 μm from the wafer surface can be reduced and also stable oxygen precipitate can be generated at high density in the bulk portion that is deeper than 30 μm. In FIG. 4H, the Si₃N₄ layer 43 is removed by etching or polishing and the final formation of DZ 46 is shown. As shown in FIG. 4I, even when the wafer is processed to have an epitaxial layer 48, the DZ 46 is maintained and the density of oxygen precipitate nuclei 47 is not decreased.

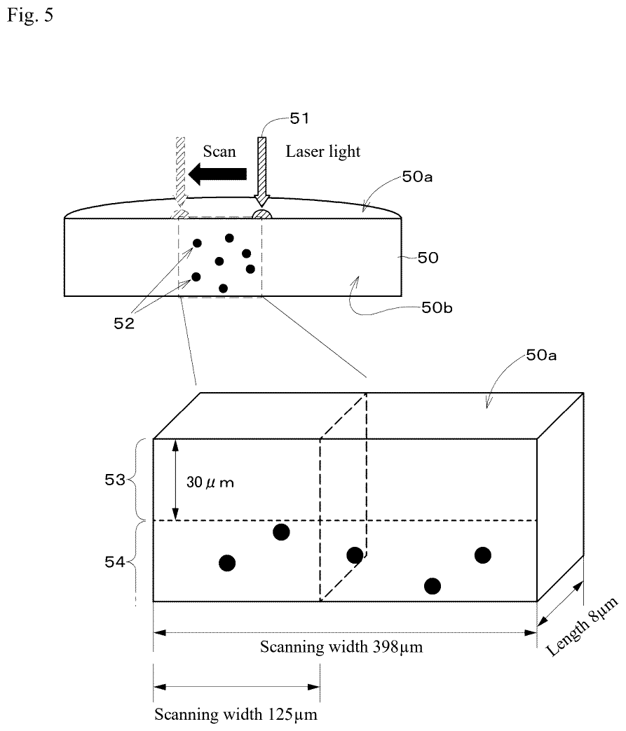

FIG. 5 is a schematic view illustrating a method of measuring an oxygen precipitate density of the silicon wafer using light-scattering tomography.

As shown in FIG. 5, oxygen precipitate of a silicon wafer 50 can be observed as a Bulk Micro Defect (BMD). The silicon wafer 50 is cleaved and infrared laser light 51 is fired from the wafer surface (main surface) 50a, and the BMD is scanned in a cleavage direction by displacing the infrared laser light 51 along a cleavage surface 50b. Since the material being examined is primarily silicon, Rayleigh-scattered light can be collected by focusing an appropriate infrared laser light on the sample. Minute dots that appear in a captured image of the cleavage surface 50b of the wafer correspond to BMD 52 and by counting the number of BMD 52 in a predetermined depth region, the BMD density within the depth region can be calculated. The wafer surface 50a is considered to have a depth of zero and the BMD density in the surface layer 53 within 30 μm from the wafer surface 50a is evaluated as surface layer BMD density, and the BMD density at the bulk portion 54 that is deeper than 30 μm, for example 50 to 300 μm from the wafer surface is evaluated as bulk BMD density.

The density of the BMD 52 is calculated by dividing the number of the BMD 52 included in a rectangle formed by a scanning width (standard condition 125 μm) that corresponds to the width of the captured image of the cleavage surface 50b, the length that corresponds to a spot diameter (standard condition 8 μm) of the infrared laser light, and a desired depth direction distance by the volume of the rectangle, and the density of the BMD 52 corresponds to the number of BMD 52 per unit volume (cm³). By increasing the scanning width up to 398 μm for example, the accuracy of BMD density measurement can be increased. Since measuring the BMD density involves cleaving and breaking the wafer, the characteristics associated with testing one wafer from one wafer batch are considered to apply to the entire wafer batch.

The silicon wafer heat-treated as described above is removed from the RTA furnace and is brought to market as a so-called annealed silicon wafer. The density of oxygen precipitate generated in the surface layer up to 30 μm from the surface of the silicon wafer according to the present embodiment is 1.0×10⁷ to 1.0×10⁸ cm⁻³, which is low. Also, the BMD layer, which refers to the layer of oxygen precipitate, is robust. The robustness here considers the change in oxygen precipitate (BMD) density from the heat treatment lower than approximately 1000° C. to the heat treatment higher than approximately 1000° C. or more, that is the range of heat treatment during a manufacturing process of a semiconductor integrated circuit. In other words, the ratio (d₂/d₁) of the average density of oxygen precipitate generated in the bulk portion by the high-temperature heat treatment (second bulk density d₂) to the average density of oxygen precipitate generated in the bulk portion by the low-temperature heat treatment (first bulk density d₁) is 0.74 to 1.02, and the change in oxygen precipitate density by heat treatment is within 30%. Even after the silicon wafer undergoes a desired heat treatment in a semiconductor device manufacturing process, the average density of oxygen precipitate in the wafer is in a range of around 4×10⁸ to 1×10¹⁰/cm³, and a fluctuation ratio of this range stays within a range of ±30%, more preferably within a range of ±15%, still more preferably within a range of ±10%, and even more preferably within a range of ±5%. In this way, the silicon wafer according to the present embodiment contains a high density of thermally stable oxygen precipitate nuclei that are not affected by a customer's heat treatment, and therefore quality and reliability of semiconductor devices such as a BCD device can be improved.

An epitaxial silicon film may also be formed on the surface of the silicon wafer that has undergone the first to third heat treatment steps S21 to S23. When the epitaxial silicon film is to be formed, the silicon wafer (silicon substrate) is exposed to a high temperature of around 1150° C., and therefore when the oxygen precipitate nuclei in the silicon wafer are thermally unstable, there is a chance that the oxygen precipitate nuclei will be lost and the oxygen precipitate density may decrease significantly following heat treatment of the device. However, according to the present embodiment, because the oxygen precipitate nuclei are thermally stable, decrease in the oxygen precipitate density can be inhibited, and a reduction in gettering capability and wafer strength can be prevented.

Both gettering capability and slip resistance are sought in a silicon wafer for manufacturing a power semiconductor device such as a BCD device, and in order to satisfy such wafer characteristics, at least 4×10⁸/cm³, and preferably approximately 1×10⁹/cm³, oxygen precipitate is believed to be needed in a silicon wafer following heat treatment of the device. For example, a conventional annealed silicon wafer manufactured by the technology described in Japanese Patent Laid-open Publication No. 2021-168382 can secure an oxygen precipitate density of around 4×10⁸/cm³ or more even when a high-temperature heat treatment such as an epitaxial growth process is performed at the initial stages of the device process. However, the oxygen precipitate density in the surface layer could not be reduced enough to secure the formation region of the device sufficiently.

However, the manufacturing method of the silicon wafer according to the present embodiment can lose oxygen precipitate nuclei (as grown nuclei) that are grown during crystal growth by quickly heating and cooling at approximately 1210° C. to 1250° C., and allowing minute oxygen precipitate nuclei to newly generate and grow inside the wafer using a heat treatment at approximately 800° C. to 975° C. continuously over a comparatively long time (about 2 to 10 minutes). The oxygen precipitate nuclei that are generated and grown inside the wafer become thermally stable and when the nuclei undergo a customer's heat treatment, a high density of oxygen precipitate can be generated regardless of what type of heat treatment is used. Moreover, by performing a high-temperature heat treatment around 1150° C. to 1250° C. continuously for about 5 to 15 minutes, the minute oxygen precipitate nuclei can be further stabilized, and surplus voids inside the wafer can diffuse out achieving both further stabilization of the oxygen precipitate nuclei density and reduction of the oxygen precipitate nuclei density in the surface layer.

A preferable embodiment of the present invention was described above, but the present invention is not limited to the embodiment noted above, and various modifications are possible without departing from the scope of the present invention, and such modifications are, of course, covered by the scope of the present invention.

### EXAMPLES

### Prediction of Three-stage Heat Treatment

A P-type silicon single crystal ingot with a diameter of 300 mm and orientation (100) was grown using the CZ method. A CZ silicon wafer was produced by slicing the silicon single crystal ingot. Next, the CZ silicon wafer was heat treated and two annealed silicon wafer samples were produced according to each of Example A1 and Comparative examples A1 to A3.

In producing the annealed silicon wafer according to Example A1, a silicon wafer (CZ silicon wafer) with an oxygen concentration of 8×10¹⁷ atom/cm³ (ASTM F-121, 1979) was used, and a three-stage heat treatment step was performed using an RTA device, in the order of first heat treatment step (high temperature 1)→second heat treatment step (low temperature)→third heat treatment step (high temperature 2). More specifically, feed-in at room temperature→increase temperature by 50°/sec→hold at 1250° C. for 10 seconds→decrease temperature by 70° C./sec→hold at 900° C. for 5 minutes→increase temperature by 50° C./sec→hold at 1200° C. for 5 minutes→decrease temperature by 10° C./sec→extraction at room temperature. An Ar gas containing ammonia was used as the atmospheric gas during the first heat treatment step and an Ar gas not containing ammonia was used as the atmospheric gas during the second and third heat treatment steps. In this way, an annealed silicon wafer sample was obtained according to Example A1.

In producing the annealed silicon wafer according to Comparative example A1, the heat treatment was performed under the same conditions as in Example A1, except that the temperature in the first heat treatment step was 1150° C. In this way, an annealed silicon wafer sample was obtained according to Comparative example A1.

In producing the annealed silicon wafer according to Comparative example A2, the heat treatment was performed under the same conditions as in Example A1, except that the temperature in the third heat treatment step was 1000° C. and the sustained time was for 1 minute.

In producing the annealed silicon wafer according to Comparative example A3, the heat treatment was performed under the same conditions as in Example A1, except that a silicon wafer with an oxygen concentration of 11×10¹⁷ atom/cm³ (ASTM F-121, 1979) was used and the temperature in the first heat treatment step was set at 1150° C., and the temperature in the third heat treatment step was 1000° C., and the sustained time was for 1 minute.

Table 1 summarizes the heat treatment conditions of Example A1 and Comparative examples A1 to A3.

TABLE 1

| | Oxygen concentration | First heat treatment | Second heat treatment | Third heat treatment |
|---|---|---|---|---|
| Sample | (atoms/cm³) | (NH₃/Ar atmosphere) | (Ar atmosphere) | (Ar atmosphere) |
| Example A1 | 8E+17 | 1250° C./10 s | 900° C./5 min | 1200° C./5 min |
| Comp. example A1 | 8E+17 | 1150° C./10 s | 900° C./5 min | 1200° C./5 min |
| Comp. example A2 | 8E+17 | 1250° C./10 s | 900° C./5 min | 1000° C./1 min |
| Comp. example A3 | 11E+17 | 1150° C./10 s | 900° C./5 min | 1000° C./1 min |

Next, to one of two samples of each annealed silicon wafer, a combination of a heat treatment that assumes the thermal history of the initial device process and a heat treatment that manifests oxygen precipitate nuclei (first evaluation heat treatment) was performed, and to the other sample, a combination of a heat treatment mimicking an epitaxial film formation process and a heat treatment that manifests oxygen precipitate nuclei (second evaluation heat treatment) was performed. The first evaluation heat treatment was configured as a two-stage heat treatment where the low-temperature heat treatment was performed at 780° C. for 3 hours and the visualization heat treatment was performed at 950° C. for 16 hours in that order. Also, the second evaluation heat treatment was configured as a two-stage heat treatment where the high-temperature heat treatment was performed at 1150° C. for 2 minutes and the visualization heat treatment was performed at 1000° C. for 16 hours in that order.

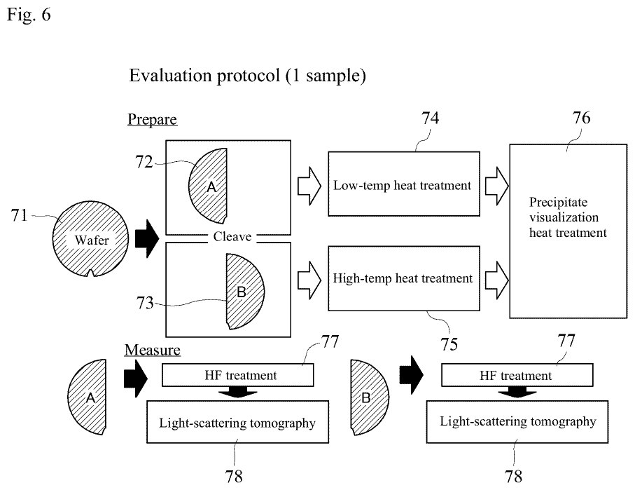

FIG. 6 is a schematic view illustrating an evaluation protocol for determining the stability and uniformity of the manufactured silicon wafer.

As shown in FIG. 6, a silicon wafer 71 to be evaluated is cleaved and divided into two portions. A portion A 72 undergoes a low-temperature heat treatment 74 and a precipitate visualization heat treatment 76 in that order, and further, a portion B 73 undergoes a high-temperature heat treatment 75 and the precipitate visualization heat treatment 76 in that order. Alternatively, two wafers from a prepared wafer batch may be used as the two wafers representing characteristics associated with the entire batch. Next, each of the wafer portions undergoes an HF treatment 77 to remove an oxide film from the surface, and then oxygen precipitate density distribution of each is determined using light-scattering tomography 78. In this way, oxygen precipitate in each of the two portions is evaluated to enable evaluating the stability of the wafer, that is, the ratio of the BMD density generated as a result of each portion undergoing the evaluation heat treatment at different temperatures and different sustained times. Since the above evaluation protocol is destructive, attributing to the entire wafer batch the characteristics associated with a wafer test from the wafer batch may be acceptable.

Next, for each sample after the evaluation heat treatment the BMD density of the surface layer within 30 μm from the wafer surface and the BMD density of the bulk portion deeper than the surface layer were measured in a desired radial direction from the center of the wafer to the edge at approximately 5 mm intervals (30 measurement points) using an infrared-scattering tomography device, and the average value was found. The diameter of the infrared laser light of the infrared-scattering tomography device was 8 μm (standard condition) and the measurement range (scanning width) per measurement point was 398 μm, which was wider than the standard condition in order to measure the surface layer BMD density as accurately as possible. Further, the ratio (BMD density ratio d₂/d₁) of the bulk BMD density after the second evaluation heat treatment (second bulk density d₂) to the bulk BMD density after the first evaluation heat treatment (first bulk density d₁) was obtained as an index of stability. Furthermore, the ratio dₘₐₓ/dₘᵢₙ of the maximum value dₘₐₓ to the minimum value dₘᵢₙ of the bulk BMD density at 30 points measured in the radial direction was used as a measure of uniformity. Evaluation results are shown in Table 2.

TABLE 2

| | Bulk BMD density (cm⁻³) | | | | | | |
|---|---|---|---|---|---|---|---|
| | | | | Uniformity | | | |
| | Stability | | | First | Second | Surface layer BMD density (cm⁻³) | |
| | First | Second | | evaluation heat | evaluation heat | First | Second |
| | evaluation heat | evaluation heat | BMD | treatment | treatment | evaluation heat | evaluation heat |
| Sample | treatment | treatment | density | dₘₐₓ/dₘᵢₙ | dₘₐₓ/dₘᵢₙ | treatment | treatment |
| Example A1 | 6.6E+09 | 6.5E+09 | 0.98 | 1.27 | 1.25 | 2.1E+07 | 2.1E+07 |
| Comp. | 9.3E+08 | 9.3E+08 | 1.00 | 1.24 | 1.30 | 6.1E+08 | 5.8E+08 |
| example A1 | | | | | | | |
| Comp. | 6.5E+09 | 2.1E+08 | 0.03 | 1.28 | 8.53 | 2.1E+07 | 2.1E+07 |
| example A2 | | | | | | | |
| Comp. | 9.4E+08 | 9.3E+08 | 0.99 | 1.30 | 1.32 | 7.0E+08 | 6.5E+08 |
| example A3 | | | | | | | |

### Example A1

In Example A1, the bulk BMD density after the first evaluation heat treatment was 6.6×10⁹ cm⁻³ and the bulk BMD density after the second evaluation heat treatment was 6.5×10⁹ cm⁻³, and the bulk BMD density ratio was 0.98. There was almost no difference between the two bulk BMD densities after the evaluation heat treatments, confirming they were very stable. Further, the surface layer BMD density after the first evaluation heat treatment was 2.1×10⁷ cm⁻³ and the surface layer BMD density after the second evaluation heat treatment was 2.1×10⁷ cm⁻³, and the BMD density was confirmed to be at least two orders of magnitude lower than the bulk BMD density. The uniformity of BMD density was also confirmed to be good, with the ratio (dₘₐₓ/dₘᵢₙ) of the maximum value dₘₐₓ to the minimum value dₘᵢₙ of the bulk BMD density in the radial direction of the wafer being almost 1 (2 or less).

### Comparative Example A1

In Comparative example A1, the BMD density after the first evaluation heat treatment was 9.3×10⁸ cm⁻³ and the BMD density after the second evaluation heat treatment was also 9.3×10⁸ cm^{31 3}, and the bulk BMD density ratio was 1.00. Thus, the bulk BMD density after evaluation heat treatment was confirmed to be very stable. Further, the uniformity of BMD density was also confirmed to be good, with the ratio (dₘₐₓ/dₘᵢₙ) of the maximum value dₘₐₓ to the minimum value dₘᵢₙ of the BMD density in the radial direction of the wafer being almost 1 (2 or less). However, as for the surface layer BMD density, the surface layer BMD density after the first evaluation heat treatment was 6.1×10⁸ cm⁻³ and the surface layer BMD density after the second evaluation treatment was 5.8×10⁸ cm⁻³, showing an increase in the surface layer BMD density. This is believed to be because the temperature of the first heat treatment was low and the effect of losing the oxygen precipitate generated at the stage of growing the crystal was insufficient.

### Comparative Example A2

In Comparative example A2, the BMD density after the first evaluation heat treatment was 6.5×10⁹ cm⁻³ and the BMD density after the second evaluation heat treatment was 2.1×10⁸ cm⁻³, and the bulk BMD density ratio was 0.03. Thus, when the temperature was low and time was short in the third heat treatment, insufficient combination of the oxygen precipitate nuclei and therefore the BMD density after the second evaluation heat treatment including a 2-minute high-temperature heat treatment at 1150° C., mimicking the epitaxial film formation process, was confirmed to decrease. Further, the uniformity of BMD density also deteriorated along with the decrease of the BMD density after the second evaluation heat treatment. As for the surface layer BMD density, both the surface layer BMD density after the first evaluation heat treatment and the surface layer BMD density after the second evaluation heat treatment were 2.1×10⁷ cm⁻³, a low density on the 10⁷ cm⁻³ level.

### Comparative Example A3

In Comparative example A3, the bulk BMD density having a good stability and uniformity was secured because of high oxygen concentration. On the other hand, increase in the surface layer BMD density was observed where the surface layer BMD density after the first evaluation heat treatment was 7.0×10⁸ cm⁻³ and the surface layer BMD density after the second evaluation heat treatment was 6.5×10⁸ cm⁻³.

### Evaluation of First Heat Treatment Step

An evaluation was conducted into how differences in heating conditions in the first heat treatment step may affect the stability and uniformity of the BMD density in the silicon wafer after evaluation heat treatment. The oxygen concentration of the silicon wafer being used was 8×10¹⁷ atoms/cm³ and the second heat treatment step and the third heat treatment step had shared conditions. Specifically, the second heat treatment step was performed in an Ar atmosphere and held a low temperature of 900° C. for 5 minutes. The third heat treatment step was performed in an Ar atmosphere and held a high temperature of 1200° C. for 5 minutes.

In Examples B1, B2, and Comparative example B1, the temperature in the first heat treatment step was set at 1210° C. for all, and the sustained time was set to 20 seconds, 60 seconds, and 10 seconds, respectively. In Examples B3 and B4, the temperature in the first heat treatment step was set at 1250° C. for both, and the sustained time was set to 10 seconds and 60 seconds, respectively. Table 3 summarizes the heat treatment conditions of Examples B1 to B4, and Comparative example B1. In addition, evaluation results are shown in Table 4.

TABLE 3

| | Oxygen concentration | First heat treatment | Second heat treatment | Third heat treatment |
|---|---|---|---|---|
| Sample | (atoms/cm³) | (NH₃/Ar atmosphere) | (Ar atmosphere) | (Ar atmosphere) |
| Example B1 | 8E+17 | 1210° C./20 s | 900° C./5 min | 1200° C./5 min |
| Example B2 | 8E+17 | 1210° C./60 s | 900° C./5 min | 1200° C./5 min |
| Example B3 | 8E+17 | 1250° C./10 s | 900° C./5 min | 1200° C./5 min |
| Example B4 | 8E+17 | 1250° C./60 s | 900° C./5 min | 1200° C./5 min |
| Comp. example B1 | 8E+17 | 1210° C./10 s | 900° C./5 min | 1200° C./5 min |

TABLE 4

| | Bulk BMD density (cm⁻³) | | | | | | |
|---|---|---|---|---|---|---|---|
| | | | | Uniformity | | | |
| | Stability | | | First | Second | Surface layer BMD density (cm⁻³) | |
| | First | Second | | evaluation heat | evaluation heat | First | Second |
| | evaluation heat | evaluation heat | BMD | treatment | treatment | evaluation heat | evaluation heat |
| Sample | treatment | treatment | density | dₘₐₓ/dₘᵢₙ | dₘₐₓ/dₘᵢₙ | treatment | treatment |
| Example B1 | 1.0E+09 | 1.0E+09 | 1.00 | 1.27 | 1.24 | 2.1E+07 | 2.1E+07 |
| Example B2 | 3.1E+09 | 2.9E+09 | 0.94 | 1.24 | 1.30 | 2.1E+07 | 2.1E+07 |
| Example B3 | 6.6E+09 | 6.5E+09 | 0.98 | 1.26 | 1.28 | 1.0E+07 | 1.0E+07 |
| Example B4 | 6.5E+09 | 6.6E+09 | 1.02 | 1.23 | 1.32 | 1.0E+07 | 1.0E+07 |
| Comp. | 3.1E+09 | 2.8E+09 | 0.90 | 1.24 | 1.28 | 7.0E+08 | 4.7E+08 |
| example B1 | | | | | | | |

As shown in Table 4, as for the stability of the bulk BMD density, in Examples B1 to B4 and Comparative example B1, the bulk BMD density after the first and second evaluation heat treatments was on the 10⁹ cm⁻³ level and the BMD density ratio was in the range of 0.90 to 1.02. In other words, the bulk BMD density was confirmed to be stable regardless of the differences in the subsequent first and second evaluation heat treatments.

On the other hand, as for the surface layer BMD density, in Examples B1 to B4, the surface layer BMD density after the first and second evaluation heat treatments was low, on the 10⁷ cm⁻³ level, while in Comparative example B1, the surface layer BMD density after the first and second evaluation heat treatments was high, on the 10⁸ cm⁻³ level. In other words, when the first heat treatment conditions were not sufficient, the outward diffusion effect in the surface layer was insufficient and the surface layer BMD density was confirmed not to decrease sufficiently.

As for the uniformity of the bulk BMD density, in each of Examples B1 to B4, and Comparative example B1, the ratio (dₘₐₓ/dₘᵢₙ) of the maximum value dₘₐₓ to the minimum value dₘᵢₙ of the bulk BMD density in the radial direction of the wafer was less than 2 and no deterioration in an in-plane uniformity of the bulk BMD density was observed.

### Evaluation of Second Heat Treatment Step

An evaluation was conducted into how differences in heating conditions in the second heat treatment step may affect the stability and uniformity of the BMD density in the silicon wafer after evaluation heat treatment. The oxygen concentration of the bulk silicon wafer being used was 8×10¹⁷ atoms/cm³ and the first heat treatment step and the third heat treatment step had shared conditions. Specifically, the first heat treatment step was performed in an Ar atmosphere that includes NH₃ and used a high temperature RTA at 1250° C. for 10 seconds. The third heat treatment step was performed in an Ar atmosphere and held a high temperature of 1200° C. for 5 minutes.

In Examples C1, C2, and Comparative example C5, the temperature in the second heat treatment step was set at 800° C. for all, and the sustained time was set to 2 minutes, 10 minutes, and 1 minute, respectively. In Examples C3, C4, and Comparative example C6, the temperature in the second heat treatment step was set at 900° C. for all, and the sustained time was set to 2 minutes, 10 minutes, and 1 minute, respectively. In Examples C5 and C6, the temperature in the second heat treatment step was set at 975° C. for both, and the sustained time was set to 5 minutes and 10 minutes, respectively. In Comparative examples C1 and C2, the temperature in the second heat treatment step was set at 775° C. for both, and the sustained time was set to 2 minutes and 10 minutes, respectively. In Comparative examples C3 and C4, the temperature in the second heat treatment step was set at 775° C. for both, and the sustained time was set to 2 minutes and 10 minutes, respectively. Table 5 summarizes the heat treatment conditions of Examples C1 to C6, and Comparative examples C1 to C6. In addition, evaluation results are shown in Table 6.

TABLE 5

| | Oxygen concentration | First heat treatment | Second heat treatment | Third heat treatment |
|---|---|---|---|---|
| Sample | (atoms/cm³) | (NH₃/Ar atmosphere) | (Ar atmosphere) | (Ar atmosphere) |
| Example C1 | 8E+17 | 1250° C./10 s | 800° C./2 min | 1200° C./5 min |
| Example C2 | 8E+17 | 1250° C./10 s | 800° C./10 min | 1200° C./5 min |
| Example C3 | 8E+17 | 1250° C./10 s | 900° C./2 min | 1200° C./5 min |
| Example C4 | 8E+17 | 1250° C./10 s | 900° C./10 min | 1200° C./5 min |
| Example C5 | 8E+17 | 1250° C./10 s | 975° C./5 min | 1200° C./5 min |
| Example C6 | 8E+17 | 1250° C./10 s | 975° C./10 min | 1200° C./5 min |
| Comp. example C1 | 8E+17 | 1250° C./10 s | 775° C./2 min | 1200° C./5 min |
| Comp. example C2 | 8E+17 | 1250° C./10 s | 775° C./10 min | 1200° C./5 min |
| Comp. example C3 | 8E+17 | 1250° C./10 s | 1000° C./2 min | 1200° C./5 min |
| Comp. example C4 | 8E+17 | 1250° C./10 s | 1000° C./10 min | 1200° C./5 min |
| Comp. example C5 | 8E+17 | 1250° C./10 s | 800° C./1 min | 1200° C./5 min |
| Comp. example C6 | 8E+17 | 1250° C./10 s | 975° C./1 min | 1200° C./5 min |

TABLE 6

| | Bulk BMD density (cm⁻³) | | | | | | |
|---|---|---|---|---|---|---|---|
| | | | | Uniformity | | | |
| | Stability | | | First | Second | Surface layer BMD density (cm⁻³) | |
| | First | Second | | evaluation heat | evaluation heat | First | Second |
| | evaluation heat | evaluation heat | BMD | treatment | treatment | evaluation heat | evaluation heat |
| Sample | treatment | treatment | density | dₘₐₓ/dₘᵢₙ | dₘₐₓ/dₘᵢₙ | treatment | treatment |
| Example C1 | 5.0E+09 | 3.7E+09 | 0.74 | 1.22 | 1.25 | 1.0E+07 | 1.0E+07 |
| Example C2 | 5.4E+09 | 4.6E+09 | 0.85 | 1.23 | 1.26 | 1.0E+07 | 1.0E+07 |
| Example C3 | 6.5E+09 | 6.2E+09 | 0.95 | 1.25 | 1.27 | 1.0E+07 | 1.0E+07 |
| Example C4 | 7.0E+09 | 6.3E+09 | 0.82 | 1.30 | 1.27 | 1.0E+07 | 1.0E+07 |
| Example C5 | 5.8E+09 | 5.0E+09 | 0.86 | 1.24 | 1.22 | 1.0E+07 | 1.0E+07 |
| Example C6 | 6.4E+09 | 5.3E+09 | 0.83 | 1.21 | 1.24 | 1.0E+07 | 1.0E+07 |
| Comp. | 4.3E+09 | 1.7E+09 | 0.40 | 2.25 | 2.42 | 1.0E+07 | 1.0E+07 |
| example C1 | | | | | | | |
| Comp. | 4.6E+09 | 2.2E+09 | 0.48 | 2.13 | 2.38 | 1.0E+07 | 1.0E+07 |
| example C2 | | | | | | | |
| Comp. | 4.3E+09 | 1.1E+09 | 0.26 | 13.3 | 13.8 | 1.0E+07 | 1.0E+07 |
| example C3 | | | | | | | |
| Comp. | 4.6E+09 | 1.2E+09 | 0.26 | 17.3 | 17.4 | 1.0E+07 | 1.0E+07 |
| example C4 | | | | | | | |
| Comp. | 4.1E+09 | 1.5E+09 | 0.37 | 2.27 | 2.44 | 1.0E+07 | 1.0E+07 |
| example C5 | | | | | | | |
| Comp. | 4.2E+09 | 1.9E+09 | 0.45 | 2.31 | 2.49 | 1.0E+07 | 1.0E+07 |
| example C6 | | | | | | | |

As shown in Table 6, as for the stability of the bulk BMD density, in Examples C1 to C6, the bulk BMD density after the first and second evaluation heat treatments was on the 10⁹ cm⁻³ level and the BMD density ratio was in the range of 0.74 to 0.95. In other words, the bulk BMD density was confirmed to be generally stable regardless of the differences in the subsequent evaluation heat treatment conditions.

In contrast, in Comparative examples C1 to C6, the bulk BMD density after the second evaluation heat treatment was decreased compared to the bulk BMD density after the first evaluation heat treatment, and the bulk BMD density ratio gave a result below 0.5. When the temperature of the second heat treatment is too low or too high, BMD nuclei in the bulk portion do not grow and are considered to have been lost by undergoing the second evaluation heat treatment. Further, when the sustained time is too short even though the temperature of the second heat treatment is proper, the BMD nuclei in the bulk portion also do not grow and are considered to be lost by undergoing the second evaluation heat treatment that includes a heat treatment mimicking the epitaxial film formation process.

As for the surface layer BMD density, in all Examples C1 to C6 and Comparative examples C1 to C6, the surface layer BMD density after the first and second evaluation heat treatments was low, on the 10⁷ cm⁻³ level. In other words, the surface layer BMD density was confirmed to be stable at low density regardless of the heat treatment conditions undergone afterwards.

As for the uniformity of the bulk BMD density, similarly to the evaluation of stability of the bulk BMD density, Examples C1 to C6 showed favorable results, however, in Comparative examples C1 to C6, the ratio (dₘₐₓ/dₘᵢₙ) of the maximum value dₘₐₓ to the minimum value dₘᵢₙ of the bulk BMD density was greater than 2 and deterioration in uniformity of the bulk BMD density was observed. It is considered that the oxygen precipitate nuclei were not sufficiently stabilized.

### Evaluation of Third Heat Treatment Step

An evaluation was conducted into how differences in heating conditions in the third heat treatment step may affect the stability and uniformity of the BMD density in the silicon wafer after evaluation heat treatment. The oxygen concentration of the silicon wafer being used was 8×10¹⁷ atoms/cm³ and the first heat treatment step and the second heat treatment step had shared conditions. Specifically, the first heat treatment step was performed in an Ar atmosphere that includes NH₃ and used a high temperature RTA at 1250° C. for 10 seconds. The second heat treatment step was performed in an Ar atmosphere and held a low temperature of 900° C. for 5 minutes.

In Examples D1, D2, and D3, the temperature in the third heat treatment step was set at 1150° C. for all, and the sustained time was set to 5 minutes, 10 minutes, and 15 minutes, respectively. In Examples D4, D5, and D6, the temperature in the third heat treatment step was set at 1200° C. for all, and the sustained time was set to 5 minutes, 10 minutes, and 15 minutes, respectively. In Examples D7, D8, and D9, the temperature in the third heat treatment step was set at 1250° C. for all, and the sustained time was set to 5 minutes, 10 minutes, and 15 minutes, respectively. In Comparative examples D1, D2, and D3, the temperature in the third heat treatment step was set at 1140° C. for all, and the sustained time was set to 5 minutes, 10 minutes, and 15 minutes, respectively. Table 7 summarizes the heat treatment conditions of Examples D1 to D6 and Comparative examples D1 to D6. In addition, evaluation results are shown in Table 8.

TABLE 7

| | Oxygen concentration | First heat treatment | Second heat treatment | Third heat treatment |
|---|---|---|---|---|
| Sample | (atoms/cm³) | (NH₃/Ar atmosphere) | (Ar atmosphere) | (Ar atmosphere) |
| Example D1 | 8E+17 | 1250° C./10 s | 900° C./5 min | 1150° C./5 min |
| Example D2 | 8E+17 | 1250° C./10 s | 900° C./5 min | 1150° C./10 min |
| Example D3 | 8E+17 | 1250° C./10 s | 900° C./5 min | 1150° C./15 min |
| Example D4 | 8E+17 | 1250° C./10 s | 900° C./5 min | 1200° C./5 min |
| Example D5 | 8E+17 | 1250° C./10 s | 900° C./5 min | 1200° C./10 min |
| Example D6 | 8E+17 | 1250° C./10 s | 900° C./5 min | 1200° C./15 min |
| Example D7 | 8E+17 | 1250° C./10 s | 900° C./5 min | 1250° C./5 min |
| Example D8 | 8E+17 | 1250° C./10 s | 900° C./5 min | 1250° C./10 min |
| Example D9 | 8E+17 | 1250° C./10 s | 900° C./5 min | 1250° C./15 min |
| Comp. example D1 | 8E+17 | 1250° C./10 s | 900° C./5 min | 1140° C./5 min |
| Comp. example D2 | 8E+17 | 1250° C./10 s | 900° C./5 min | 1140° C./10 min |
| Comp. example D3 | 8E+17 | 1250° C./10 s | 900° C./5 min | 1140° C./15 min |

TABLE 8

| | Bulk BMD density (cm⁻³) | | | | | | |
|---|---|---|---|---|---|---|---|
| | | | | Uniformity | | | |
| | Stability | | | First | Second | Surface layer BMD density (cm⁻³) | |
| | First | Second | | evaluation heat | evaluation heat | First | Second |
| | evaluation heat | evaluation heat | BMD | treatment | treatment | evaluation heat | evaluation heat |
| Sample | treatment | treatment | density | dₘₐₓ/dₘᵢₙ | dₘₐₓ/dₘᵢₙ | treatment | treatment |
| Example D1 | 6.9E+09 | 6.5E+09 | 0.94 | 1.27 | 1.23 | 1.0E+07 | 1.0E+07 |
| Example D2 | 6.9E+09 | 6.7E+09 | 0.97 | 1.25 | 1.25 | 1.0E+07 | 1.0E+07 |
| Example D3 | 6.9E+09 | 6.9E+09 | 1.00 | 1.26 | 1.26 | 1.0E+07 | 1.0E+07 |
| Example D4 | 6.6E+09 | 6.5E+09 | 0.98 | 1.24 | 1.30 | 1.0E+07 | 1.0E+07 |
| Example D5 | 6.6E+09 | 6.6E+09 | 1.00 | 1.30 | 1.27 | 1.0E+07 | 1.0E+07 |
| Example D6 | 6.6E+09 | 6.6E+09 | 1.00 | 1.24 | 1.23 | 1.0E+07 | 1.0E+07 |
| Example D7 | 6.0E+09 | 5.9E+09 | 0.98 | 1.28 | 1.24 | 1.0E+07 | 1.0E+07 |
| Example D8 | 6.0E+09 | 6.0E+09 | 1.00 | 1.27 | 1.26 | 1.0E+07 | 1.0E+07 |
| Example D9 | 6.0E+09 | 6.0E+09 | 1.00 | 1.30 | 1.27 | 1.0E+07 | 1.0E+07 |
| Comp. | 6.5E+09 | 9.3E+08 | 0.14 | 1.29 | 1.24 | 1.0E+07 | 1.0E+07 |
| example D1 | | | | | | | |
| Comp. | 6.5E+09 | 8.8E+08 | 0.14 | 1.26 | 1.53 | 1.0E+07 | 1.0E+07 |
| example D2 | | | | | | | |
| Comp. | 6.5E+09 | 8.4E+08 | 0.13 | 1.27 | 1.47 | 1.0E+07 | 1.0E+07 |
| example D3 | | | | | | | |

As shown in FIG. 8, as for the stability of the bulk BMD density, in Examples D1 to D9 , the bulk BMD density after the first and second evaluation heat treatments was on the 10⁹ cm⁻³ level and the BMD density ratio was in the range of 0.94 to 1.00. In other words, the bulk BMD density was confirmed to be stable regardless of the differences in the subsequent first and second evaluation heat treatments.

In contrast, in Comparative examples D1 to D3, the bulk BMD density after the second evaluation heat treatment was decreased compared to the bulk BMD density after the first evaluation heat treatment, and the bulk BMD density ratio gave a result far below 0.5. When the temperature of the third heat treatment is too low, the BMD nuclei in the bulk portion do not grow and are considered to have been lost by undergoing the second evaluation heat treatment that includes a heat treatment mimicking the epitaxial film formation process.

As for the surface layer BMD density, in all Examples D1 to D9 and Comparative examples D1 to D3, the surface layer BMD density after the first and second evaluation heat treatments was low, on the 10⁷ cm⁻³ level.

As for the uniformity of the bulk BMD density, unlike the evaluation of stability of the bulk BMD density, not only Examples D1 to D9, but also Comparative examples D1 to D3 showed favorable results. In other words, the ratio (dₘₐₓ/dₘᵢₙ) of the maximum value dₘₐₓ to the minimum value dₘᵢₙ of the bulk BMD density was 2 or less and the in-plane uniformity of the bulk BMD density was good.

### Evaluation of Oxygen Concentration of Silicon Wafer

An evaluation was conducted into how differences in oxygen concentration in the silicon wafer may affect the stability and uniformity of the BMD density in the silicon wafer after three-stage heat treatment and evaluation heat treatment. In Example E1, a low oxygen bulk silicon wafer with oxygen concentration of 7×10¹⁷ atoms/cm³ was used. In Example E2, a bulk silicon wafer with oxygen concentration of 10×10¹⁷ atoms/cm³ was used. In Comparative example E1, a bulk silicon wafer with oxygen concentration of 11×10¹⁷ atoms/cm³ was used. In Comparative example E2, a low oxygen bulk silicon wafer with oxygen concentration of 6×10¹⁷ atoms/cm³ was used. In the three-stage heat treatment, each bulk silicon wafer underwent the first heat treatment step at 1250° C. for 10 seconds, the second heat treatment step at 900° C. for 5 minutes, and the third heat treatment step at 1200° C. for 5 minutes. Table 9 summarizes the differences in oxygen concentration of Examples E1 to E2 and Comparative examples E1 to E2. In addition, evaluation results are shown in Table 10.

TABLE 9

| | Oxygen concentration | First heat treatment | Second heat treatment | Third heat treatment |
|---|---|---|---|---|
| Sample | (atoms/cm³) | (NH₃/Ar atmosphere) | (Ar atmosphere) | (Ar atmosphere) |
| Example E1 | 7E+17 | 1250° C./10 s | 900° C./5 min | 1200° C./5 min |
| Example E2 | 10E+17 | 1250° C./10 s | 900° C./5 min | 1200° C./5 min |
| Comp. example E1 | 11E+17 | 1250° C./10 s | 900° C./5 min | 1200° C./5 min |
| Comp. example E2 | 6E+17 | 1250° C./10 s | 900° C./5 min | 1200° C./5 min |

TABLE 10

| | Bulk BMD density (cm⁻³) | | | | | | |
|---|---|---|---|---|---|---|---|
| | | | | Uniformity | | | |
| | Stability | | | First | Second | Surface layer BMD density (cm⁻³) | |
| | First | Second | | evaluation heat | evaluation heat | First | Second |
| Sample | evaluation heat | evaluation heat | BMD | treatment | treatment | evaluation heat | evaluation heat |
| Sample | treatment | treatment | density | dₘₐₓ/dₘᵢₙ | dₘₐₓ/dₘᵢₙ | treatment | treatment |
| Example E1 | 6.2E+09 | 5.3E+09 | 0.85 | 1.24 | 1.30 | 1.0E+07 | 1.0E+07 |
| Example E2 | 6.9E+09 | 6.9E+09 | 1.00 | 1.30 | 1.27 | 1.0E+08 | 8.4E+07 |
| Comp. | 7.8E+09 | 7.6E+09 | 0.97 | 1.29 | 1.24 | 1.5E+08 | 1.5E+08 |
| example E1 | | | | | | | |
| Comp. | 2.3E+09 | 9.6E+08 | 0.42 | 1.69 | 13.3 | 0 | 0 |
| example E2 | | | | | | | |

As shown in Table 10, in Examples E1 and E2, the bulk BMD density and the surface layer BMD density were good.

On the other hand, in Comparative example E1 in which the bulk silicon wafer with oxygen concentration of 11×10¹⁷ atoms/cm³ was used, the bulk BMD density was good, while the surface layer BMD density increased. The in-plane uniformity of the bulk BMD density was good.

In Comparative example E2 in which the silicon wafer with oxygen concentration of 6×10¹⁷ atoms/cm³ was used, the bulk BMD density after the second evaluation heat treatment is decreased compared to the bulk BMD density after the first evaluation heat treatment, and the bulk BMD density ratio had a result below 0.5. As for the uniformity of the bulk BMD density, the ratio (dₘₐₓ/dₘᵢₙ) of the maximum value dₘₐₓ to the minimum value dₘᵢₙ of the bulk BMD density after the second evaluation heat treatment was 13.3, and similarly to the evaluation of stability of the bulk BMD density, significant deterioration in the in-plane uniformity of the bulk BMD density after the second evaluation heat treatment was observed. The in-plane uniformity of the bulk BMD density after the first evaluation heat treatment was good. As for the surface layer BMD density, the results were extremely good with no BMD observed in the surface layer after the first and second evaluation heat treatments.

### Evaluation of Effect From Epitaxial Growth

An epitaxial film was formed on the wafer manufactured by the three-stage heat treatment and stability of the BMD density after the epitaxial growth was confirmed. As shown in Table 11, in Examples F1, F2, and F3, growth temperature was set at 1050° C. for all, and the sustained time was set to 1 minute, 2 minutes, and 5 minutes, respectively. In Examples F4, F5, and F6, the growth temperature was set at 1150° C. for all, and the sustained time was set to 1 minute, 2 minutes, and 5 minutes, respectively. The thickness of the obtained epitaxial film was 2 μm in Examples F1 and F4, 4 μm in Examples F2 and F5, and 10 μm in Examples F3 and F6.

The first evaluation heat treatment of the evaluation heat treatments after the epitaxial growth is configured as a two-stage heat treatment where a low-temperature heat treatment is performed at 780° C. for 3 hours and a visualization heat treatment is performed at 950° C. for 16 hours in that order. The second evaluation heat treatment omitted 2-minute high-temperature heat treatment at 1150° C. that mimicks the epitaxial film formation process, and only performed the visualization heat treatment at 1000° C. for 16 hours. Evaluation results are shown in Table 12.

TABLE 11

| | Oxygen | | | |
|---|---|---|---|---|
| | concentration | Epitaxial growth | Epitaxial film | |
| Sample | (atoms/cm³) | condition | thickness | |
| Example F1 | 8E+17 | 1050° C./1 min | 2 | μm |
| Example F2 | 8E+17 | 1050° C./2 min | 4 | μm |
| Example F3 | 8E+17 | 1050° C./5 min | 10 | μm |
| Example F4 | 8E+17 | 1150° C./1 min | 2 | μm |
| Example F5 | 8E+17 | 1150° C./2 min | 4 | μm |
| Example F6 | 8E+17 | 1150° C./5 min | 10 | μm |

TABLE 12

| | Bulk BMD density (cm⁻³) | | | | | | |
|---|---|---|---|---|---|---|---|
| | | | | Uniformity | | | |
| | Stability | | | First | Second | Surface layer BMD density (cm⁻³) | |
| | First | Second | | evaluation heat | evaluation heat | First | Second |
| | evaluation heat | evaluation heat | BMD | treatment | treatment | evaluation heat | evaluation heat |
| Sample | treatment | treatment | density | dₘₐₓ/dₘᵢₙ | dₘₐₓ/dₘᵢₙ | treatment | treatment |
| Example F1 | 5.9E+09 | 5.9E+09 | 1.00 | 1.24 | 1.26 | 1.0E+07 | 1.0E+07 |
| Example F2 | 5.8E+09 | 5.9E+09 | 1.02 | 1.26 | 1.29 | 1.0E+07 | 1.0E+07 |
| Example F3 | 5.7E+09 | 5.7E+09 | 1.00 | 1.27 | 1.26 | 1.0E+07 | 1.0E+07 |
| Example F4 | 5.9E+09 | 5.9E+09 | 1.00 | 1.26 | 1.30 | 1.0E+07 | 1.0E+07 |
| Example F5 | 5.9E+09 | 5.9E+09 | 1.00 | 1.29 | 1.30 | 1.0E+07 | 1.0E+07 |
| Example F6 | 5.6E+09 | 5.5E+09 | 0.98 | 1.28 | 1.35 | 1.0E+07 | 1.0E+07 |

As shown in Table 12, under any epitaxial growth conditions, the stability and the uniformity of the bulk BMD density and the uniformity of the surface layer BMD density were found to be good, and the bulk BMD density was confirmed not to decrease even when the epitaxial growth was performed on the silicon wafer manufactured by the three-stage heat treatment.

### DESCRIPTION OF REFERENCE NUMERALS

S11 Step of manufacturing a silicon single crystal ingot
S12 Step of fabricating a silicon wafer
S13 Step of heat-treating a silicon wafer
S21 First heat treatment step
S22 Second heat treatment step
S23 Third heat treatment step
30 Standby temperature
32 Temperature increase
34 Temperature decrease
36 Temperature increase
40 Silicon wafer
40a Upper zone
40b Lower zone
41 Minute oxygen precipitate nuclei (generated during crystal growth)
42 Frenkel pair
43 Si₃N₄ layer
44, 44a, 44b Void
45 Interstitial silicon atom
46 DZ
47 Oxygen precipitate nuclei
47a Small oxygen precipitate nuclei
48 Epitaxial layer
50 Silicon wafer
50a Wafer surface (main surface)
50b Cleavage surface
51 Infrared laser light
52 BMD (oxygen precipitate)
53 Surface layer
54 Bulk portion
71 Silicon wafer
72 Portion A of wafer
73 Portion B of wafer
74 Low-temperature heat treatment
75 High-temperature heat treatment
76 Precipitate visualization heat treatment
77 HF treatment
78 Light-scattering tomography

1. A silicon wafer comprising a surface layer having a depth of up to 30 μm from a surface; and
a bulk portion that is deeper than the surface layer, wherein
a density of oxygen precipitate generated in the surface layer by a first evaluation heat treatment is 1.0×10⁷ cm⁻³ to 1.0×10⁸ cm⁻³,
a density of oxygen precipitate generated in the bulk portion by the first evaluation heat treatment is 1.0×10⁹ cm⁻³ to 7.0×10⁹ cm⁻³, and
when an average density of oxygen precipitate generated in the bulk portion by the first evaluation heat treatment is defined as a first bulk density, and an average density of oxygen precipitate generated in the bulk portion by a second evaluation heat treatment is defined as a second bulk density, a ratio of the second bulk density to the first bulk density is in a range of 0.74 to 1.02, and
the first evaluation heat treatment is a two-stage heat treatment in which, after a heat treatment at 780° C. for 3 hours, a visualization heat treatment is performed, and
the second evaluation heat treatment is a two-stage heat treatment in which, after a heat treatment at 1150° C. for 2 minutes, the visualization heat treatment is performed, and
the visualization heat treatment is a heat treatment performed at 950° C. to 1000° C. for 16 hours.

2. The silicon wafer according to claim 1, wherein a ratio of a maximum value to a minimum value of the density of oxygen precipitate generated in the bulk portion by the first evaluation heat treatment and a ratio of a maximum value to a minimum value of the density of oxygen precipitate generated in the bulk portion by the second evaluation heat treatment are both 2 or less.

3. The silicon wafer according to claim 1, wherein the ratio of the maximum value to the minimum value of the density of oxygen precipitate generated in the bulk portion by the first evaluation heat treatment is 1.30 or less, and the ratio of the maximum value to the minimum value of the density of oxygen precipitate generated in the bulk portion by the second evaluation heat treatment is 1.32 or less.

4. The silicon wafer according to claim 1, wherein the average density of oxygen precipitate generated in the surface layer by the first evaluation heat treatment and the average density of oxygen precipitate generated in the surface layer by the second evaluation heat treatment are both 2.1×10⁷ cm⁻³ or less.

5. A silicon wafer comprising a silicon substrate; and
an epitaxial silicon film that is formed on a surface of the silicon substrate, wherein
the silicon substrate has a surface layer having a depth of up to 30 μm from the surface and a bulk portion that is deeper than the surface layer,
a density of oxygen precipitate generated in the surface layer by a first evaluation heat treatment is 1.0×10⁷ cm⁻³ to 1.0×10⁸ cm⁻³,
a density of oxygen precipitate generated in the bulk portion by the first evaluation heat treatment is 1.0×10⁹ cm⁻³ to 7.0×10⁹ cm⁻³,
when an average density of oxygen precipitate generated in the bulk portion by the first evaluation heat treatment is defined as a first bulk density, and an average density of oxygen precipitate generated in the bulk portion by the second evaluation heat treatment is defined as a second bulk density, a ratio of the second bulk density to the first bulk density is in a range of 0.98 to 1.02,
the first evaluation heat treatment is a two-stage heat treatment in which, after a heat treatment at 780° C. for 3 hours, a visualization heat treatment is performed,
the second evaluation heat treatment is the visualization heat treatment, and
the visualization heat treatment is a heat treatment performed at 950° C. to 1000° C. for 16 hours.

6. The silicon wafer according to claim 5, wherein the ratio of the maximum value to the minimum value of the density of oxygen precipitate generated in the bulk portion by the first evaluation heat treatment and the ratio of the maximum value to the minimum value of the density of oxygen precipitate generated in the bulk portion by the second evaluation heat treatment are both 2 or less.

7. The silicon wafer according to claim 6, wherein the ratio of the maximum value to the minimum value of the density of oxygen precipitate generated in the bulk portion by the first evaluation heat treatment is 1.29 or less and the ratio of the maximum value to the minimum value of the density of oxygen precipitate generated in the bulk portion by the second evaluation heat treatment is 1.35 or less.

8. A manufacturing method of the silicon wafer comprising:
a first heat treatment of heating a silicon wafer having an oxygen concentration of 7×10¹⁷ atoms/cm³ to 10×10¹⁷ atoms/cm³ (ASTM F-121, 1979) at a first temperature;
a second heat treatment of heating the silicon wafer, after the first heat treatment, at a second temperature that is lower than the first temperature; and
a third heat treatment of heating the silicon wafer, after the second heat treatment, at a third temperature that is higher than the second temperature, wherein
the first temperature is 1210° C. to 1250° C., and a sustained time of the first temperature is 10 to 60 seconds,
the second temperature is 800° C. to 975° C., and the sustained time of the second temperature is 2 to 10 minutes, and
the third temperature is 1150° C. to 1250° C., and the sustained time of the third temperature is 5 to 15 minutes.

9. The manufacturing method of the silicon wafer according to claim 8,
wherein the first heat treatment is performed in a non-oxidizing atmosphere that contains ammonia or nitrogen, and
the second and the third heat treatments are performed in a non-oxidizing atmosphere that does not contain ammonia or nitrogen.

10. The manufacturing method of the silicon wafer according to claim 8, wherein a rate of temperature increase to the first temperature and a rate of temperature increase from the second temperature to the third temperature are 10° C./sec to 50° C./sec.

11. The manufacturing method of the silicon wafer according to claim 8, wherein a rate of temperature decrease from the first temperature to the second temperature is 20° C./sec to 120° C./sec.

12. The manufacturing method of the silicon wafer according to claim 8, wherein the silicon wafer prior to heat treatment in the first heat treatment is cut from a denuded zone of a silicon single crystal ingot without aggregates of interstitial silicon point defects and aggregates of vacancy point defects.
